(19) United States
(12) Patent Application Publication
(10) Pub. No.: US 2025/0273104 A1
(43) Pub. Date: Aug. 28, 2025

(54) Micro-LED Display Device and Method of Testing the Same

(71) Applicant: LG Display Co., Ltd., Seoul (KR)

(72) Inventor: Young Jin Kim, Paju-si (KR)

(21) Appl. No.: 19/062,664

(22) Filed: Feb. 25, 2025

(30) Foreign Application Priority Data
Feb. 27, 2024 (KR) 10-2024-0028195

(51) Int. Cl. G09G 3/00; G09G 3/32

(52) U.S. Cl. CPC G09G 3/006; G09G 3/32; G09G 2300/0426

(57) ABSTRACT

A micro-led display device and method of testing the same are disclosed. A display panel includes pixels divided into pixel groups. Each of the pixels includes a light-emitting element connected to a first electrode configured to supply an anode voltage and a second electrode configured to supply a cathode voltage. The light-emitting element includes an anode connected to the first electrode and a cathode connected to the second electrode. Anodes of light-emitting elements included in each pixel group are connected to each other. The light-emitting element emits light by receiving the cathode voltage controlled such that a difference between the anode voltage and the cathode voltage is greater than or equal to a threshold voltage of the light-emitting element. A test voltage is applied to the cathode of the light-emitting element to detect whether an electrical short circuit has occurred between the first electrode and the second electrode.

### CROSS-REFERENCE TO RELATED APPLICATION

This application claims priority to and the benefit of Republic of Korea Patent Application No. 10-2024-0028195, filed on Feb. 27, 2024, which is hereby incorporated by reference in its entirety.

### BACKGROUND

### Field of Technology

The present disclosure relates to a micro-light-emitting diode (micro-LED) display device and a method of testing the same. More specifically, the present disclosure relates to a micro-LED display device and a method of testing the same, in which a test voltage is applied to a cathode of a light-emitting element instead of a cathode voltage to detect whether a short circuit has occurred between electrodes.

### Discussion of Related Art

With the development of the information society, the demand for various types of display devices for displaying images is increasing, and the demand for lightweight and thin display devices is also increasing. Accordingly, various types of display devices, such as liquid crystal display (LCD) devices, plasma display panel (PDP), electroluminescent display devices, electrowetting display devices, electrophoresis display (EPD) devices, organic light-emitting diodes (OLEDs) display devices, and micro-light-emitting diodes (micro-LEDs) display devices, mini-light-emitting diodes (mini-LED), flexible display devices, etc. are being developed.

Micro-LEDs are generally LEDs having a side with a size of 100 μm or less. The size corresponds to a size that is about 1/10 or less of that of general LEDs, and due to such an ultra-small size, micro-LEDs have advantages in terms of a heat generation amount and a power consumption amount and are known to have energy efficiency that is about 20% higher than general LEDs. Due to these advantages, much research is being conducted to apply micro-LEDs to display devices. Since a large number of light-emitting elements are transferred during a transfer process of micro-light-emitting elements, it is important to accurately test whether the light-emitting elements are defective.

In a pre-test of displays using micro-LEDs as pixels, whether a defect has occurred is determined in units of pixels, and when the defect has occurred, sub-light-emitting elements are set to be driven instead of main light-emitting elements. However, only a pre-test is performed on functional defects of light-emitting elements, and a separate test is not performed to determine whether a short due to transfer defects in the light-emitting elements has occurred between electrodes to which a voltage for driving the light-emitting elements is supplied.

### SUMMARY

The inventors have recognized the above-described limitations and propose the present disclosure.

The present disclosure is directed to providing a micro-light-emitting diode (micro-LED) display device and a method of testing the same, in which a test voltage is applied to a cathode of a light-emitting element instead of a cathode voltage to detect whether a short circuit has occurred between electrodes.

The present disclosure is directed to providing a micro-LED display device and a method of testing the same, in which, when an electrical short circuit between electrodes is detected by applying a test voltage to a cathode of a light-emitting element, sub-light-emitting elements are driven instead of main light-emitting elements of all of detected pixel and pixels associated therewith.

The objects of the present disclosure are not limited to those described above, and other objects not described may become apparent to those of ordinary skill in the art based on the following descriptions.

According to an embodiment of the present disclosure, there is provided a display panel including a plurality of pixels divided into a plurality of pixel groups, wherein each of the plurality of pixels includes light-emitting elements connected to a first electrode configured to supply an anode voltage and a second electrode configured to supply a cathode voltage, each of the light-emitting elements includes an anode electrically connected to the first electrode and a cathode electrically connected to the second electrode, anodes of light-emitting elements included in each pixel group are electrically connected to each other, the light-emitting element emits light by receiving the cathode voltage controlled such that a difference between the anode voltage and the cathode voltage is greater than or equal to a threshold voltage of the light-emitting element, and a test voltage is applied to the cathode of the light-emitting element instead of the cathode voltage to detect whether an electrical short circuit has occurred between the first electrode and the second electrode.

According to another embodiment of the present disclosure, there is provided a display device including a display panel which includes a plurality of pixels divided into a plurality of pixel groups, wherein each of the plurality of pixels includes light-emitting elements connected to a first electrode configured to supply an anode voltage and a second electrode configured to supply a cathode voltage, each of the light-emitting elements includes an anode electrically connected to the first electrode and a cathode electrically connected to the second electrode, anodes of light-emitting elements included in each pixel group are electrically connected to each other, the light-emitting element emits light by receiving the cathode voltage controlled such that a difference between the anode voltage and the cathode voltage is greater than a threshold voltage of the light-emitting element, and a test voltage is applied to the cathode of the light-emitting element instead of the cathode voltage to detect whether an electrical short circuit has occurred between the first electrode and the second electrode.

Specific details of other embodiments are included in the detailed description and drawings.

### BRIEF DESCRIPTION OF THE DRAWINGS

The above and other objects, features and advantages of the present disclosure will become more apparent to those of ordinary skill in the art by describing exemplary embodiments thereof in detail with reference to the accompanying drawings, in which:

FIG. 1 is a view illustrating a display device according to one embodiment of the present disclosure;

FIG. 2 is an enlarged view illustrating area A of FIG. 1 according to one embodiment of the present disclosure;

FIG. 3 is a view illustrating some areas of a pixel according to one embodiment of the present disclosure;

FIG. 4 is a cross-sectional view along line I-I′ of FIG. 3 according to one embodiment

of the present disclosure;

FIG. 5 is a cross-sectional view along line II-II′ of FIG. 3 according to one embodiment of the present disclosure;

FIG. 6 is a cross-sectional view along line III-III′ of FIG. 3 according to one embodiment of the present disclosure;

FIG. 7 is a cross-sectional view illustrating an example in which a main light-emitting element and a sub-light-emitting element are electrically connected to a pixel driving circuit according to one embodiment of the present disclosure;

FIG. 8 is a view illustrating a display device according to another embodiment of the present disclosure;

FIG. 9 is a cross-sectional view along line IV-IV′ of FIG. 8 according to one embodiment of the present disclosure;

FIG. 10 is a view illustrating a state in which a pre-test is performed on a display device according to one embodiment of the present disclosure;

FIG. 11 shows views illustrating alternative driving when a defect of a light-emitting element is detected in FIG. 10 according to one embodiment of the present disclosure;

FIG. 12 is a conceptual circuit diagram illustrating a case in which an electrical short circuit has occurred in one light-emitting element according to one embodiment of the present disclosure;

FIG. 13 is a flowchart illustrating a method of detecting whether an electrical short has occurred between electrodes by applying a test voltage according to one embodiment of the present disclosure;

FIGS. 14A and 14B show views illustrating a state in which whether a light-emitting element emits light in FIG. 13 is visually checked according to one embodiment of the present disclosure;

FIG. 15 shows views illustrating alternative driving when an electrical short circuit between electrodes is detected according to one embodiment of the present disclosure;

FIG. 16 shows views illustrating a case in which short-circuit resistance is low according to one embodiment of the present disclosure; and

FIG. 17 shows views illustrating a case in which short-circuit resistance is high according to one embodiment of the present disclosure.

### DETAILED DESCRIPTION

The advantages and features of the present disclosure and methods of accomplishing the same will become apparent from the following description of the embodiments in detail, taken in conjunction with the accompanying drawings. However, the present disclosure is not limited to the embodiments disclosed herein but will be implemented in various forms. The embodiments are provided so that the present disclosure is completely disclosed, and a person of ordinary skilled in the art can fully understand the scope of the present disclosure. Therefore, the present disclosure will be defined only by the scope of the appended claims.

A shape, a size, a ratio, an angle, and a number disclosed in the drawings for describing embodiments of the present disclosure are merely an example, and thus, the present disclosure is not limited to the illustrated details. Like reference numerals refer to like elements throughout the disclosure. In addition, in describing the present disclosure, when it is determined that the specific description of the known related art unnecessarily obscures the gist of the present disclosure, the detailed description thereof will be omitted. The terms such as “including,” “comprising,” “having,” “containing,” and “constituting” used herein are generally intended to allow other components to be added unless the terms are used with a term such as “merely,” “only,” etc. Any references to singular may include plural unless expressly stated otherwise.

Components are interpreted to include an ordinary error range even if not expressly stated. The expression that an element is “connected,” “coupled,” or “adhered” to another element or layer, the element or layer can not only be directly connected or adhered to another element or layer, but also be indirectly connected or adhered to another element or layer with one or more intervening elements or layers “disposed,” or “interposed” between the elements or layers, unless otherwise specified.

When the position relation between two parts is described using the terms such as “on,” “above,” “over,” “under,” “below,” “beside” and “next,” one or more parts may be positioned between the two parts unless the terms are expressly limited, for example, by the terms such as “immediately” or “directly.”

When the temporal relationship between two events is described using the terms “after,” “following,” “next,” and “before”, the two events may not occur in succession as long as the term such as “immediately” or “directly” is not used.

The features of various embodiments of the present disclosure can be partially or entirely adhered to, coupled to or combined with each other and can be interlocked and operated in technically various ways, and the embodiments can be carried out independently of or in association with each other.

Hereinafter, a micro-light-emitting diode (micro-LED) display device and a method of testing the same according to an embodiment of the present disclosure will be described with reference to the accompanying drawings.

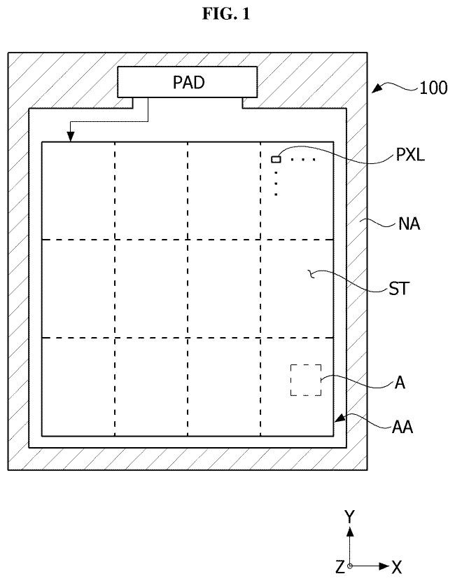

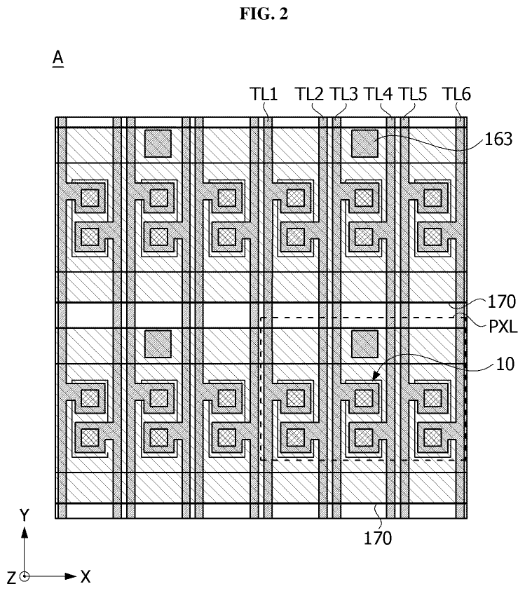

FIG. 1 is a view illustrating a display device according to one embodiment of the present disclosure. FIG. 2 is an enlarged view illustrating area A of FIG. 1 according to one embodiment of the present disclosure.

Referring to FIGS. 1 and 2, a display device 100 according to the embodiment of the present disclosure includes a display panel on which an input image or video is visually reproduced. The display panel may include a display area AA in which an image is displayed and a non-display area NA in which an image is not displayed and which is located outside the display area AA. Various lines and driving circuits may be mounted in the non-display area NA, and a pad unit PAD to which an integrated circuit, a printed circuit, and the like are connected may be disposed in the non-display area NA.

A plurality of light-emitting elements 10 disposed in the display area AA to form pixels PXLs may be micro-sized inorganic light-emitting elements, but not limited thereto. The inorganic light-emitting element may be grown on a silicon wafer and then attached to the display panel through a transfer process.

The transfer process of the light-emitting element 10 may be performed for each pre-partitioned area. In FIG. 1, the display area AA is illustrated as being partitioned into 12 transfer areas ST, but the size of the transfer areas or the number of partitions thereof is not limited thereto. The transfer process may be performed unsimultaneously (e.g., sequentially) or simultaneously on first to e.g. twelfth transfer areas ST. In the transfer area ST, a blue light-emitting element 10, a green light-emitting element 10, and a red light-emitting element 10 may be (e.g., sequentially) transferred, but not limited thereto. Light-emitting element of other color systems such as CMYK may also be adopted.

A data driving circuit, a gate driving circuit, a sensing driving circuit or the like may be disposed in the non-display area NA, and lines to which a control signal for controlling such driving circuits is supplied may be disposed. Here, the control signal may include various timing signals including a clock signal, an input data enable signal, and a synchronization signal such as a vertical synchronization (VSYNC) signal or a horizontal synchronization (HSYNC) signal and may be received through the pad unit PAD.

The pixels PXL may be driven by a pixel driving circuit. The pixel driving circuit may receive a driving voltage, an image/video signal (digital signal), a synchronization signal synchronized with the image/video signal, and the like and may output an anode voltage and a cathode voltage of the light-emitting element 10 to drive a plurality of pixels. The driving voltage may be a high potential voltage EVDD. The cathode voltage may be a low potential voltage EVSS commonly applied to the pixels. The anode voltage may be a voltage corresponding to a pixel data value of the image signal. The pixel driving circuit may be disposed in the non-display area NA or may be disposed below the display area AA, but not limited thereto.

Each pixel PXL may include a plurality of subpixels each having a different color. For example, the plurality of pixels may include a red subpixel including the light-emitting element 10 that emits light with a red wavelength, a green subpixel including the light-emitting element 10 that emits light with a green wavelength, and a blue subpixel including the light-emitting element 10 that emits light with a blue wavelength. The plurality of pixels may further include white pixels, but not limited thereto.

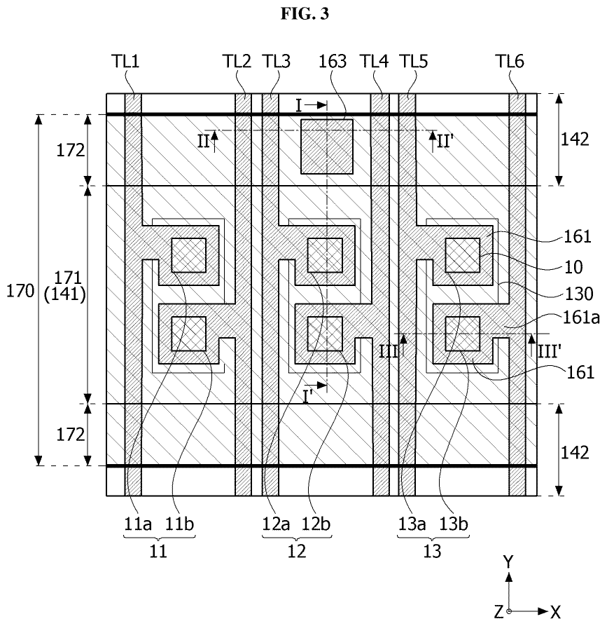

Referring to FIGS. 2 and 3, a plurality of pixels PXL may be consecutively disposed in a first direction (e.g., X-axis direction) and a second direction (e.g., Y-axis direction). A plurality of subpixels with the same color may be disposed in a pixel in a display area AA. For example, each of the plurality of pixels may include a first red subpixel in which a 1-1 light-emitting element 11a emitting light with a red wavelength is disposed, a second red subpixel in which a 1-2 light-emitting element 11b emitting light with a red wavelength is disposed, a first green subpixel in which a 2-1 light-emitting element 12a emitting light with a green wavelength is disposed, a second green subpixel in which a 2-2 light-emitting element 12b emitting light with a green wavelength is disposed, a first blue subpixel in which a 3-1 light-emitting element 13a emitting light with a blue wavelength is disposed, and a second blue subpixel in which a 3-2 light-emitting element 13b emitting light with a blue wavelength is disposed. The 1-1 light-emitting element 11a, the 2-1 light-emitting element 12a, and the 3-1 light-emitting element 13a may be interpreted as main light-emitting elements. The 1-2 light-emitting element 11b, the 2-2 light-emitting element 12b, and the 3-2 light-emitting element 13b may be interpreted as sub-light-emitting elements.

A subpixel may include at least one light-emitting element, and thus when one light-emitting element becomes defective, the luminance of the subpixel may be adjusted by increasing the luminance of other light-emitting elements. However, the present disclosure is not necessarily limited thereto, and one subpixel may include only one light-emitting element.

A plurality of first electrodes 161 may each disposed below the light-emitting element 10 and may be optionally connected to a plurality of signal lines TL1 to TL6 by a connection portion 161a. A high potential voltage may be applied to the pixel driving circuit through the signal lines TL1 to TL6, but not limited thereto. The signal lines TL1 to TL6 and the first electrodes 161 may be formed as electrode patterns integrated with an anode during an electrode pattern process.

For example, a first signal line TL1 may be connected to an anode of the first red subpixel, and a second signal line TL2 may be connected to an anode of the second red subpixel. A third signal line TL3 may be connected to an anode of the first green subpixel, and a fourth signal line TL4 may be connected to an anode of the second green subpixel. A fifth signal line TL5 may be connected to an anode of the first blue subpixel, and a sixth signal line TL6 may be connected to an anode of the second blue subpixel. When one subpixel includes only one light-emitting element, the number of signal lines TL may be reduced by half.

A second electrode 170 may be a cathode that is disposed in each row to apply a cathode voltage to the light-emitting elements 10 consecutively disposed in the first direction (e.g., X-axis direction). A plurality of second electrodes 170 may be disposed to be spaced apart from each other in the second direction (e.g., Y-axis direction). A cathode voltage may be applied to the plurality of second electrodes 170 through a contact electrode 163. The plurality of second electrodes 170 may each be electrically connected to the contact electrode 163. However, the present disclosure is not necessarily limited thereto, and the second electrode 170 may be provided as one electrode layer rather than being divided into a plurality of pieces and may function as a common electrode.

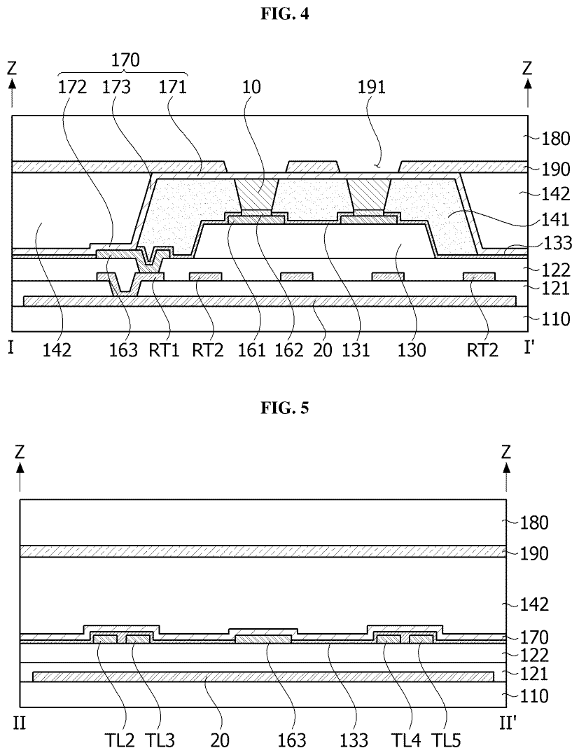

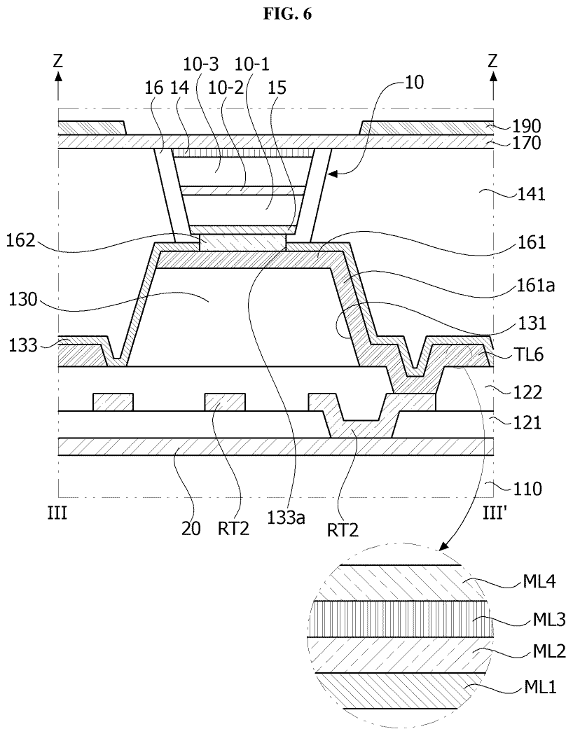

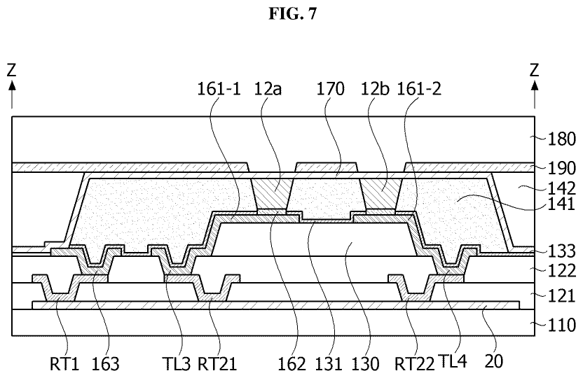

FIG. 4 is a cross-sectional view along line I-I′ of FIG. 3 according to one embodiment. FIG. 5 is a cross-sectional view along line II-II′ of FIG. 3 according to one embodiment. FIG. 6 is a cross-sectional view along line III-III′ of FIG. 3 according to one embodiment. FIG. 7 is a cross-sectional view illustrating an example in which two light-emitting elements are connected to a pixel driving circuit according to one embodiment.

Referring to FIGS. 3 to 5, a display device according to an embodiment includes a plurality of first electrodes 161 and a plurality of contact electrodes 163 which are disposed on a substrate 110, a plurality of light-emitting elements 10 disposed on the plurality of first electrodes 161, a first optical layer 141 disposed between the plurality of light-emitting elements 10, and a second electrode 170 disposed on the plurality of light-emitting elements 10.

The substrate 110 may be made of plastic having flexibility. For example, the substrate 110 may be manufactured as a single-layer or multi-layer substrate made of a material including one or more of polyimide, polyethylene terephthalate, acrylonitrile-butadiene-styrene copolymer, polymethyl methacrylate, polyethylene naphthalate, polycarbonate, polyethersulfone, polyarylate, polysulfone, a cyclic-olefin copolymer, triacetylcellulose, polyvinyl alcohol, and polystyrene, but the present disclosure is not limited thereto. For example, the substrate 110 may be a ceramic substrate or a glass substrate.

A pixel driving circuit 20 may be disposed in a display area AA of the substrate 110. The pixel driving circuit 20 may include a plurality of thin film transistors using an amorphous silicon semiconductor, a polycrystalline silicon semiconductor, or an oxide semiconductor, but not limited thereto.

The pixel driving circuit 20 may include at least one driving thin film transistor, at least one switching thin film transistor, and at least one storage capacitor, among others. When the pixel driving circuit 20 includes a plurality of thin film transistors, the plurality of thin film transistors may be formed on the substrate 110 through a thin film transistor (TFT) manufacturing process. In an embodiment, the pixel driving circuit 20 may be a general term for a plurality of thin film transistors electrically connected to the light-emitting element 10.

The pixel driving circuit 20 may be a driving driver manufactured on a single crystal semiconductor substrate 110 using a metal-oxide-silicon field effect transistor (MOSFET) manufacturing process. The driving driver may include a plurality of pixel driving circuits to drive a plurality of subpixels. When the pixel driving circuit 20 is implemented as a driving driver, after an adhesive layer is disposed on the substrate 110, the driving driver may be mounted on the adhesive layer through a transfer process.

A buffer layer 121 covering the pixel driving circuit 20 may be disposed on the substrate 110. The buffer layer 121 may be made of an organic insulating material, for example, benzocyclobutene, photosensitive photo acryl or photosensitive polyimide, but the present disclosure is not limited thereto.

The buffer layer 121 may be used by stacking inorganic insulating materials such as silicon nitride (SiNx), silicon oxide (SiOy), silicon oxynitride (SiNxOy) in a plurality of layers or may be used by stacking organic insulating materials and inorganic insulating materials in a plurality of layers.

An insulating layer 122 may be disposed on the buffer layer 121. The insulating layer 122 may be made of an organic insulating material, for example, benzocyclobutene, photosensitive photo acryl or photosensitive polyimide, but the present disclosure is not limited thereto. Connection lines RT1 and RT2 may be disposed on the buffer layer 121. The connection lines RT1 and RT2 may be connected to corresponding signal lines TL1 to TL6 or may be connected to any combination among the signal lines TL1 to TL6. The connection lines RT1 and RT2 may include a plurality of line patterns disposed on different layers with one or more insulating layers therebetween. The line patterns disposed on different layers may be electrically connected through a contact hole passing through the insulating layer.

A plurality of bank patterns 130 may be disposed on the insulating layer 122. At least one light-emitting element 10 may be disposed on each bank pattern 130. For example, a first light-emitting element 11 may be disposed on a first bank pattern 130, a second light-emitting element 12 may be disposed on a second bank pattern 130, and a third light-emitting element 13 may be disposed on a third bank pattern 130.

The bank pattern 130 may be made of an organic insulating material, for example, benzocyclobutene, photosensitive photo acryl or photosensitive polyimide, but the present disclosure is not limited thereto. The bank pattern 130 may guide a position at which the light-emitting element 10 is to be attached during a transfer process of the light-emitting element 10. The bank pattern 130 may be omitted.

A solder pattern 162 may be disposed on a first electrode 161. The solder pattern 162 may be made of indium (In), tin (Sn), or an alloy thereof, but the present disclosure is not limited thereto.

The plurality of light-emitting elements 10 may each be mounted on the solder pattern 162. One pixel may include the light-emitting elements 10 having three colors. The first light-emitting element 11 may be a red light-emitting element, the second light-emitting element 12 may be a green light-emitting element, and the third light-emitting element 13 may be a blue light-emitting element, but not limited thereto. As an alternative, the first light-emitting element 11 may be a cyan light-emitting element, the second light-emitting element 12 may be a magenta light-emitting element, the third light-emitting element 13 may be a yellow element. Two light-emitting elements may be installed in each subpixel.

The first optical layer 141 may surround the plurality of light-emitting elements 10 and may cover the bank patterns 130. Accordingly, the first optical layer 141 may be disposed to include an area between the plurality of light-emitting elements 10 and an area between the plurality of bank patterns 130. The first optical layers 141 may extend in a first direction X and may be spaced apart from each other in a second direction Y.

The first optical layer 141 may include an organic insulating material in which fine metal particles such as titanium dioxide particles are dispersed. Light emitted from the plurality of light-emitting elements 10 may be scattered by the fine metal particles dispersed in the first optical layer 141 and emitted to the outside.

The second electrode 170 may be disposed on the plurality of light-emitting elements 10. The second electrode 170 may be commonly connected to a plurality of pixels PXL. The second electrode 170 may be a thin electrode that transmits light. The second electrode 170 may be made of a transparent electrode material, for example, indium tin oxide (ITO), indium zinc oxide (IZO), but the present disclosure is not necessarily limited thereto.

The second electrodes 170 may extend in the first direction X and may be spaced apart from each other in the second direction Y. The second electrode 170 may include a first area 171 disposed on an upper surface of the light-emitting element 10 and an upper surface of the first optical layer 141, a second area 172 in contact with the contact electrode 163 and electrically connected to the contact electrode 163, and a third area 173 disposed on a side surface of the first optical layer 141 to connect the first area 171 and the second area 172 of the second electrode 170.

In a plane view, a plurality of second electrodes 170 may each overlap the first optical layer 141, and the second area 172 may cover an outer planar surface of the contact electrode 163.

A second optical layer 142 may be made of an organic insulating material to surround the first optical layer 141. The second optical layer 142 may be disposed on the insulating layer 122 together with the first optical layer 141. The first optical layer 141 and the second optical layer 142 may include the same material (for example, siloxane). For example, the first optical layer 141 may be made of siloxane including titanium oxide (TiOx), but not limited thereto, and the second optical layer 142 may be made of siloxane not including titanium oxide (TiOx). However, the present disclosure is not necessarily limited thereto, and the first optical layer 141 and the second optical layer 142 may be made of the same material or different materials.

According to an embodiment, since the second area 172 of the second electrode 170 is connected to the contact electrode 163 in a state in which the entirety of the second area 172 is formed to be flat, excessive stress is not concentrated at a point at which the second area 172 is connected to the contact electrode 163. Accordingly, it is possible to effectively reduce or prevent cracks from occurring in the second electrode 170.

As shown in FIG. 4, the second optical layer 142 may cover the second area 172 and the third area 173 of the second electrode 170. An upper surface of the second optical layer 142 may be coplanar with an upper surface of the first area 171 of the second electrode 170. For example, the first optical layer 141 and the second optical layer 142 may function as planarization layers. Thus, since there is no step on a surface on which a black matrix 190 is formed, patterns of the black matrix 190 may be easily formed on the first optical layer 141 and the second optical layer 142. However, the present disclosure is not necessarily limited thereto, and the upper surfaces of the second optical layer 142 and the second electrode 170 may have different heights.

The black matrix 190 may be made of an organic insulating material to which a black pigment such as carbon black and graphite is added. The second electrode 170 may be in contact with the contact electrode 163 below the black matrix 190. A transmission hole 191 through which light emitted from the light-emitting element 10 is emitted to the outside may be formed between the patterns of the black matrix 190. A problem in that beams of light emitted from adjacent light-emitting elements 10 are mixed may be solved by the black matrix 190.

A cover layer 180 may be made of an organic insulating material to cover the black matrix 190 and the second electrode 170. In FIG. 3, the configuration of the black matrix 190 and the cover layer 180 is omitted.

The contact electrode 163 may be electrically connected to a first connection line RT1 disposed there below, and the first connection line RT1 may be connected to the pixel driving circuit 20. Therefore, a cathode voltage may be applied to the second electrode 170 through the contact electrode 163. The first electrode 161 may be electrically connected to a second connection line RT2. This will be described below.

Referring to FIG. 5, the contact electrode 163 may be coplanar with the signal lines TL1 to TL6. The pixel driving circuit 20 may be disposed below the contact electrode 163 and the signal lines TL1 to TL6. When the pixel driving circuit 20 is a driving driver, a plurality of driving drivers may be disposed in a display panel.

A passivation layer 133 may expose the contact electrode 163 such that the contact electrode 163 and the second electrode 170 are electrically connected. In addition, the passivation layer 133 may insulate the signal lines TL2 to TL5 from the second electrode 170.

Referring to FIG. 6, a connection portion 161a of the first electrode 161 may extend to one side surface 131 of the bank pattern 130 to be connected to the connection line RT2 disposed on the buffer layer 121.

The first electrode 161, the connection portion 161a, the signal line TL, and/or the connection line RT2 may include a single-layer or multi-layer metal layer made of a material including one or more of titanium (Ti), molybdenum (Mo), and aluminum (Al), but not limited thereto. The first electrode 161, the connection portion 161a, the signal line TL, and/or the connection line RT2 may be formed as a multilayer structure including a first layer ML1, a second layer ML2, a third layer ML3, and a fourth layer ML4, but not limited thereto.

The first layer ML1 and the third layer ML3 may include titanium (Ti) or molybdenum (Mo), but not limited thereto. The second layer ML2 may include aluminum (Al), but not limited thereto. The fourth layer ML4 may include a transparent conductive oxide layer made of indium tin oxide (ITO), indium zinc oxide (IZO) or indium tin zinc oxide (InSnZnO) which has high adhesiveness to the solder pattern 162 and has corrosion resistance and acid resistance.

The first layer ML1, the second layer ML2, the third layer ML3, and the fourth layer ML4 may be sequentially deposited and then patterned by performing a photolithography process and an etching process.

The passivation layer 133 may be disposed on the first electrode 161 and the signal line TL6 and may include an opening 133a that exposes the solder pattern 162.

The light-emitting element 10 may include a first conductive-type semiconductor layer 10-1, an active layer 10-2 disposed on the first conductive-type semiconductor layer 10-1, and a second conductive-type semiconductor layer 10-3 disposed on the active layer 10-2. A first driving electrode 15 may be disposed below the first conductive-type semiconductor layer 10-1, and a second driving electrode 14 may be disposed on the second conductive-type semiconductor layer 10-3.

The light-emitting element 10 may be formed on a silicon wafer using a method including metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), or sputtering, but not limited thereto.

The first conductive-type semiconductor layer 10-1 may be implemented using a Group III-V or Group II-VI compound semiconductor or the like and may be doped with a first dopant. The first conductive-type semiconductor layer 10-1 may be made of at least one or more of a semiconductor material having a composition formula of Alx1InylGa(1−x1−-y1)N (0≤x1≤1, 0≤y1≤1, and 0≤x1+y1≤1), such as InAlGaN, AlGaAs, GaP, GaAs, GaAsP, and AlGaInP, but the present disclosure is not limited thereto. When the first dopant is an n-type dopant such as Si, Ge, Sn, Se, or Te, the first conductive-type semiconductor layer 10-1 may be an n-type nitride semiconductor layer. However, when the first dopant is a p-type dopant, the first conductive-type semiconductor layer 10-1 may be a p-type nitride semiconductor layer.

The active layer 10-2 is a layer in which electrons (or holes) injected through the first conductive-type semiconductor layer 10-1 meet holes (or electrons) injected through the second conductive-type semiconductor layer 10-3. As electrons and holes recombine, while an energy level of the electrons in the active layer 10-2 transitions to a lower energy level, the active layer 10-2 may generate light with a corresponding wavelength.

The active layer 10-2 may have any one structure of a single well structure, a multi-well structure, a single quantum well structure, a multi-quantum well (MQW) structure, a quantum dot structure, and a quantum wire structure, and the structure of the active layer 10-2 is not limited thereto. The active layer 10-2 may generate light in a visible light wavelength range. For example, the active layer 10-2 may output light with a wavelength range of any one of blue, green, and red, but not limited thereto.

The second conductive-type semiconductor layer 10-3 may be disposed on the active layer 10-2. The second conductive-type semiconductor layer 10-3 may be implemented using a Group III-V or Group II-VI compound semiconductor or the like and may be doped with a second dopant. The second conductive-type semiconductor layer 10-3 may be made of a semiconductor material having a composition formula of Inx2Aly2Ga(1−x2−y2)N (0≤x2≤1, 0≤y2≤1, and 0≤x2+y2≤1) or a material selected from AlInN, AlGaAs, GaP, GaAs, GaAsP, and AlGaInP. When the second dopant is a p-type dopant such as Mg, Zn, Ca, Sr, or Ba, the second conductive-type semiconductor layer 10-3 doped with the second dopant may be a p-type semiconductor layer. When the second dopant is an n-type dopant, the second conductive-type semiconductor layer 10-3 may be an n-type nitride semiconductor layer.

A reflection layer 16 may be disposed on a side surface and a lower surface of the light-emitting element 10. The reflection layer 16 may have a structure in which a reflection material is dispersed in a resin layer, but the present disclosure is not necessarily limited thereto. For example, the reflection layer 16 may be manufactured as a reflector with various structures. Light emitted from the active layer 10-2 may be reflected upward by the reflection layer 16, thereby increasing light extraction efficiency.

In the embodiment, a vertical structure in which the driving electrodes 14 and 15 are disposed on and below a light-emitting structure has been described, but the light-emitting element may have a lateral structure or a flip chip structure in addition to the vertical structure.

Referring to FIG. 7, a main light-emitting element 12a and a sub-light-emitting element 12b of a subpixel may be disposed on the bank pattern 130. The second light-emitting element 12 is described as an example. A 1-1 electrode 161-1 connected to the main light-emitting element 12a may be electrically connected to a 2-1 connection line RT21 that extends to one side surface of the bank pattern 130 and is disposed there below. A 1-2 electrode 161-2 connected to the sub-light-emitting element 12b may be electrically connected to a 2-2 connection line RT22 that extends to the other side surface of the bank pattern 130 and is disposed there below.

The pixel driving circuit 20 may apply an anode voltage to the main light-emitting element 12a through the 2-1 connection line RT21 and may apply an anode voltage to the sub-light-emitting element 12b through the 2-2 connection line RT22. The pixel driving circuit 20 may apply a cathode voltage to the main light-emitting element 12a and the sub-light-emitting element 12b through the first connection line RT1 and the second electrode 170.

The pixel driving circuit 20 may adjust luminance by driving only the main light-emitting element 12a or may adjust luminance by simultaneously driving the main light-emitting element 12a and the sub-light-emitting element 12b. When the main light-emitting element 12a is darkened, luminance may be adjusted by driving only the sub-light-emitting element 12b.

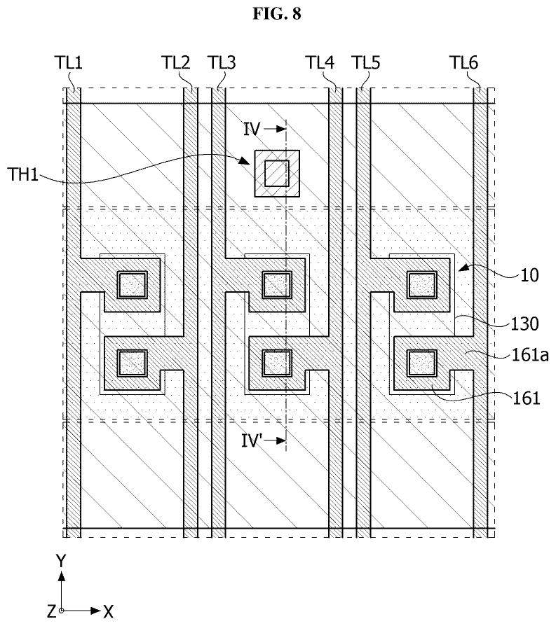

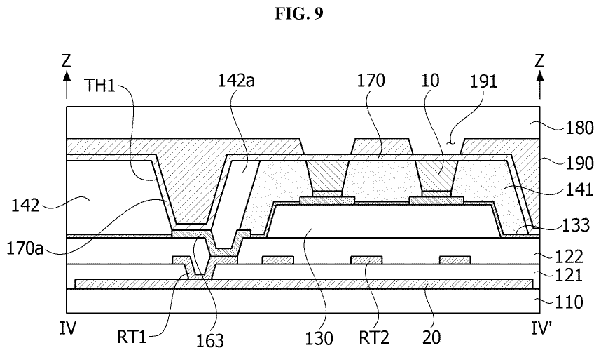

FIG. 8 is a view illustrating a display device according to another embodiment of the present disclosure. FIG. 9 is a cross-sectional view along line IV-IV′ of FIG. 8 according to one embodiment of the present disclosure.

Referring to FIGS. 8 and 9, a second electrode 170 may be electrically connected to a contact electrode 163 through a contact hole TH1 formed in a second optical layer 142. The second optical layer 142 may include the contact hole TH1 exposing the contact electrode 163. The second electrode 170 may be inserted into the contact hole TH1 of the second optical layer 142 and may be in contact with an upper surface of the contact electrode 163. The contact hole TH1 may be formed in an outer area of a pixel.

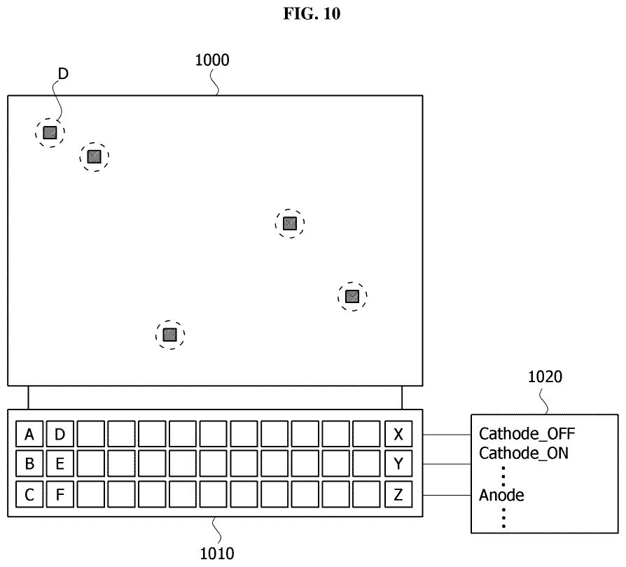

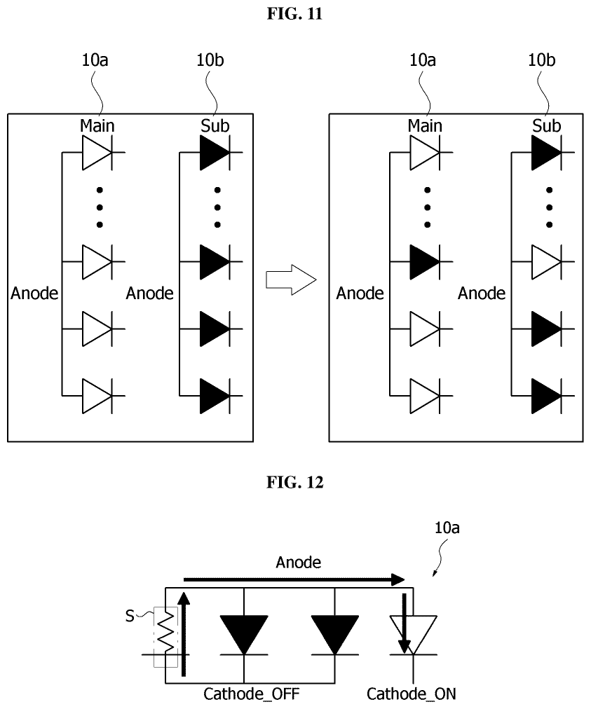

FIG. 10 is a view illustrating a state in which a pre-test is performed on a display device according to one embodiment of the present disclosure. FIG. 11 shows views illustrating alternative driving when a defect of a light-emitting element is detected in FIG. 10 according to one embodiment of the present disclosure.

A pre-test may be performed on cells formed on a substrate of a display panel 1000, and a test may be performed through a method in which a voltage corresponding to each pin is applied to a cell pad 1010 through a power supply 1020 to drive the cells. In the pre-test, a functional test in the cell is generally performed, and when a defect D occurs in a unit of a pixel as shown in FIG. 10, as shown in FIG. 11, a sub-light-emitting element is driven instead of a corresponding main light-emitting element, and each pixel for each sample has information about the driving of the main light-emitting element or the sub-light-emitting element. For reference, in the drawings below FIG. 11, light-emitting elements illustrated in white are in a turned-on state, and light-emitting elements illustrated in black are in a turned-off state.

Meanwhile, light-emitting elements 10 according to one embodiment of the present disclosure may be micro-sized inorganic light-emitting elements and may have a structure in which anodes of a plurality of light-emitting elements are electrically connected to each other, for example, a structure in which anode terminals of N light-emitting elements 10 (e.g., 10a, or 10b) are connected to each other through one node as shown in FIG. 11, wherein N may be an integer larger than one. In summary, a plurality of pixels PXL of a display area AA may be divided into a plurality of pixel groups including N pixels as shown in FIG. 11, and anodes of light-emitting elements may be electrically connected to each other for each of the pixels (for example, the N pixels) in each pixel group. Meanwhile, the micro-sized inorganic light-emitting element may be, more specifically, an ultra-small light-emitting element having a size of 100 um or less.

Referring again to FIGS. 1 and 2, the plurality of pixels PXL disposed in the display area AA may be consecutively disposed in a first direction (X-axis direction) which is a row direction and a second direction (Y-axis direction) which is a column direction. For each disposed column, the plurality of pixels PXL may be divided into a plurality of pixel groups including N pixels as shown in FIG. 11, and the anodes of the light-emitting elements may be electrically connected to each other for each of the pixels (for example, the N pixels) in each pixel group.

The light-emitting element 10 may be driven in a manner in which the light-emitting element (e.g., sequentially) emits light for one pixel at a time among the pixels (for example, N pixels) in each pixel group according to a driving time. In other words, when the light-emitting element of one pixel in the pixel group is turned on, the light-emitting elements of other pixels in the pixel group maintain a turned-off state, and the pixels of which the light-emitting elements are turned on are (e.g., sequentially) changed according to a driving time.

Referring to FIG. 11, a main light-emitting element 10a may emit light by a cathode voltage being controlled with a cathode-on voltage for turning on the light-emitting element to emit light and a cathode-off voltage for turning off the light-emitting element to not emit light, and the cathode voltage may be individually controlled for each of the pixels in the pixel group. More specifically, the cathode-on voltage may be set such that its difference from an anode voltage is greater than a threshold voltage of the light-emitting element, thereby turning on the light-emitting element, and the cathode-off voltage may be set such that its difference from the anode voltage is less than the threshold voltage of the light-emitting element, thereby causing the light-emitting element to be in a turn-off state without being turned on.

Referring again to FIG. 10, powers for driving a circuit of the display panel 1000 are supplied to the cell pad 1010, and the power supplied in this manner also includes a cathode-on voltage Cathode_ON and a cathode-off voltage Cathode_OFF which are powers for individually driving the light-emitting elements sharing an anode.

As described above, since a short circuit test is not separately performed on the light-emitting element in a pre-test stage, whether there is a short circuit may not be determined. This is because, since the short circuit is particularly problematic in light-emitting elements such as micro-LEDs that have a structure in which anodes of a plurality of light-emitting elements are electrically connected to each other, when a short circuit has occurred in one light-emitting element, the light-emitting elements of all pixels in a pixel group including a pixel in which the short circuit has occurred may abnormally operate. In such a case, driving a sub-light-emitting element instead of only a defective main light-emitting element may degrade image quality.

FIG. 12 is a conceptual circuit diagram illustrating a case in which an electrical short circuit has occurred in one light-emitting element.

Referring to FIG. 12, when a cathode-on voltage Cathode_ON is applied to a light-emitting element of one pixel among main light-emitting elements 10a in a pixel group to turn on the light-emitting element, a cathode-off voltage Cathode_OFF is applied to light-emitting elements 10b of other pixels in the pixel group to maintain a turned-off state, and pixels of which light-emitting elements are turned on are (e.g., sequentially) changed according to a driving time. When an electrical short circuit S has occurred in one light-emitting element of the main light-emitting elements 10a in the pixel group, since a cathode-off voltage, which is a voltage that is relatively less than an anode voltage Anode, is applied to a node through which anode terminals of the light-emitting elements are connected, a light-emitting element at a light-emitting timing is not normally driven.

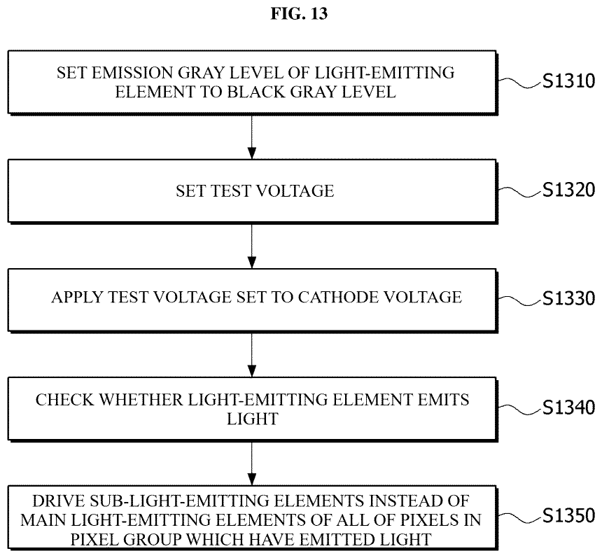

FIG. 13 is a flowchart illustrating a method of detecting whether an electrical short has occurred between electrodes by applying a test voltage according to one embodiment of the present disclosure.

The method of detecting whether an electrical short has occurred between electrodes by applying a test voltage according to one embodiment of the present disclosure may include operation S1310 of setting an emission gray level of a light-emitting element to a black gray level, operation S1320 of setting a test voltage, operation S1330 of applying the test voltage set to a cathode voltage, operation S1340 of checking whether the light-emitting element emits light, and operation S1350 of driving sub-light-emitting elements instead of main light-emitting elements of all pixels in a pixel group which have emitted light.

In operation S1310, the emission gray level of the light-emitting element is set to a black gray level, and thus pixels that emit light may be distinguished and recognized by applying a test voltage. In operations S1320 and S1330, the test voltage may be applied instead of a cathode-off voltage Cathode_OFF, and a voltage greater than a cathode-on voltage Cathode_ON by a threshold voltage of the light-emitting element or more may be set and applied to an anode of the light-emitting element to cause the light-emitting element to emit light at a black gray level. In addition, the test voltage may be set to a range in which the light-emitting element in a pixel group in which a short circuit has occurred may emit light at a higher gray level than a black gray level, and thus pixels in a pixel group in which a short circuit has not occurred are sequentially e.g. and normally driven and recognized as being in a black state, and pixels in the pixel group in which a short circuit has occurred may be recognized as emitting light at a gray level different from a black state.

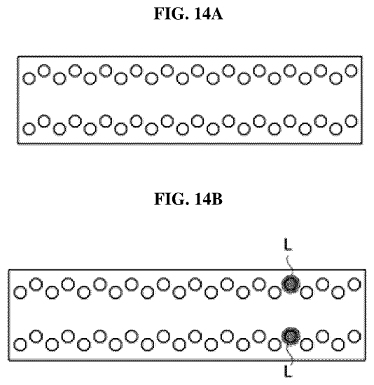

FIGS. 14A and 14B show views illustrating a state in which whether the light-emitting element emits light in FIG. 13 is visually checked according to one embodiment.

In operation S1340, as described above, as shown in FIG. 14A, the pixels in the pixel group in which a short circuit has not occurred may be sequentially e.g. and normally driven and recognized as being in a black state, and as shown in FIG. 14B, the pixels in the pixel group in which a short circuit has occurred may be recognized as emitting light L at a gray level different from a black state.

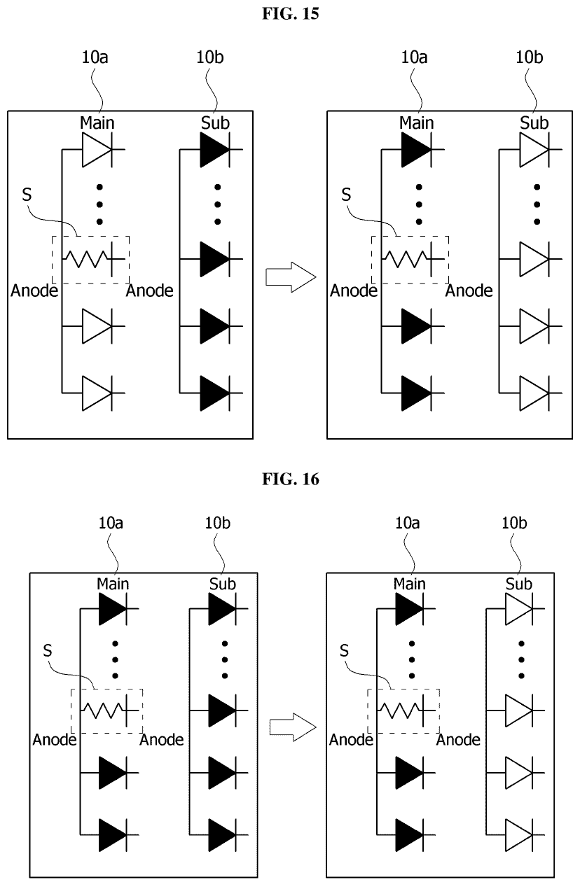

FIG. 15 shows views illustrating alternative driving when an electrical short circuit between electrodes is detected according to one embodiment of the present disclosure.

In operation S1350, sub-light-emitting elements 10b are driven instead of main light-emitting elements 10a of the pixels in the pixel group which have emitted light, for example, the main light-emitting elements 10a of all pixels in the pixel group in which a short circuit S has occurred.

In summary, referring again to FIG. 10, instead of the cathode-off voltage Cathode_OFF, which is one of powers supplied to the cell pad 1010 in the pre-test, by using a test voltage of which a voltage level simply varies under conditions as described above, in which a voltage applied to the anode through a short circuit of the light-emitting element should be greater than or equal to a threshold voltage of the light-emitting element in relation to the cathode-on voltage Cathode_ON, and the test voltage is set to have a voltage range such that the light-emitting element in a pixel group in which a short circuit has occurred may emit light at a higher gray level than a black gray level, whether an electrical short circuit has occurred between electrodes is visually detected in advance, thereby effectively reducing or minimizing losses due to defects. In addition, in the event of a short circuit, corresponding sub-light-emitting elements are preset to be driven instead of all of the main light-emitting elements having a common anode, thereby reducing or preventing degradation in image quality.

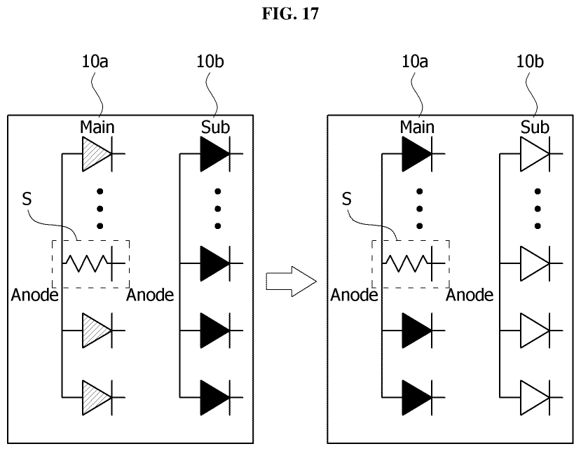

FIG. 16 shows views illustrating a case in which short-circuit resistance is low according to one embodiment. FIG. 17 shows views illustrating a case in which short-circuit resistance is high according to one embodiment.

When the resistance of a part S, at which a short circuit of a light-emitting element has occurred, is low (for example, 0 Ω), as shown in FIG. 16, a voltage of an anode of main light-emitting elements 10a sharing the anode is lowered due to the influence of a cathode-off voltage and a cathode-on voltage so that all of the main light-emitting elements 10a are turned off, and in this case, sub-light-emitting elements 10b are set through a pre-test to be driven instead of all of the main light-emitting elements 10a.

When the resistance of the part S, at which a short circuit of the light-emitting element has occurred, is high (for example, tens to hundreds of kΩ), as shown in FIG. 17, a voltage of the anode of the main light-emitting elements 10a sharing the anode is slightly lowered due to the influence of the cathode-off voltage and the cathode-on voltage, but nevertheless, the main light-emitting elements 10a emit light with weaker intensity as compared to a normal driving state, resulting in degradation in light-emitting quality. Accordingly, even in this case, the sub-light-emitting elements 10b are set through a pre-test to be driven instead of all of the main light-emitting elements 10a, thereby maintaining image quality in a normal state.

As described above, according to a micro-LED display device and a method of testing the same according to one embodiment of the present disclosure, in a pre-test operation or a separate operation, a test voltage of which a voltage level simply varies is applied to a cathode of a light-emitting element instead of a cathode voltage to visually detect whether there is an electrical short circuit due to a transfer defect or other reasons in an individual light-emitting element among a plurality of main light-emitting elements sharing an anode, such as a micro-LED, thereby reducing or minimizing losses due to defects. In addition, in the pre-test operation, corresponding sub light-emitting elements are preset to be driven instead of all of the main light-emitting elements sharing an anode, thereby reducing or preventing degradation in image quality.

Example embodiments of the present disclosure may be described as follows.

In one or more example embodiments, a display panel comprising a plurality of pixels divided into a plurality of pixel groups, wherein each of the plurality of pixels includes light-emitting elements connected to a first electrode configured to supply an anode voltage and a second electrode configured to supply a cathode voltage, wherein each of the light-emitting elements includes an anode electrically connected to the first electrode and a cathode electrically connected to the second electrode, wherein anodes of light-emitting elements included in each pixel group are electrically connected to each other, wherein the light-emitting element emits light by receiving the cathode voltage controlled such that a difference between the anode voltage and the cathode voltage is greater than or equal to a threshold voltage of the light-emitting element, and wherein a test voltage is applied to the cathode of the light-emitting element instead of the cathode voltage to detect whether an electrical short circuit has occurred between the first electrode and the second electrode.

In one or more example embodiments, a display device comprising a display panel which includes a plurality of pixels divided into a plurality of pixel groups, wherein each of the plurality of pixels includes light-emitting elements connected to a first electrode configured to supply an anode voltage and a second electrode configured to supply a cathode voltage, wherein each of the light-emitting elements includes an anode electrically connected to the first electrode and a cathode electrically connected to the second electrode, wherein anodes of light-emitting elements included in each pixel group are electrically connected to each other, wherein the light-emitting element emits light by receiving the cathode voltage controlled such that a difference between the anode voltage and the cathode voltage is greater than a threshold voltage of the light-emitting element, and wherein a test voltage is applied to the cathode of the light-emitting element instead of the cathode voltage to detect whether an electrical short circuit has occurred between the first electrode and the second electrode.

In some example embodiments, the anode voltage is controlled such that the light-emitting element emits light at a black gray level.

In some example embodiments, the cathode voltage is controlled with a first voltage for turning on the light-emitting element to emit light or a second voltage for turning off the light-emitting element to not emit light.

In some example embodiments, the first voltage is sequentially applied to the cathode of the light-emitting element for one pixel at a time among the pixels in each pixel group.

In some example embodiments, the test voltage is applied to the cathode of the light-emitting element instead of the second voltage.

In some example embodiments, the test voltage is set such that a difference from the first voltage is greater than or equal to the threshold voltage of the light-emitting element.

In some example embodiments, the electrical short circuit has occurred between the first electrode and the second electrode is detected according to whether the light-emitting elements of the pixels in the pixel group to which the test voltage is applied emit light, and the test voltage is set such that the light-emitting element emits light at a gray level higher than a black gray level.

In some example embodiments, the light-emitting element includes a main light-emitting element and a sub-light-emitting element, and the sub-light-emitting element is driven instead of the main light-emitting element when the main light-emitting element is defective.

In some example embodiments, when the electrical short circuit has occurred between the first electrode and the second electrode, sub-light-emitting elements are driven instead of main light-emitting elements of all pixels in the pixel group in which the electrical short circuit has occurred.

According to embodiments of the present disclosure, in a pre-test operation, a test voltage of which a voltage level simply varies is applied to a cathode of a light-emitting element instead of a cathode voltage to visually detect whether an electrical short circuit has occurred between electrodes, thereby reducing or minimizing losses due to defects.

According to embodiments of the present disclosure, by detecting in advance an electrical short circuit due to a transfer defect of an individual light-emitting element among a plurality of main light-emitting elements sharing an anode, such as micro-LEDs, corresponding sub-light-emitting elements are set to be driven instead of all of the main light-emitting elements sharing the anode, thereby reducing or preventing degradation in image quality.

The effects of the present disclosure are not limited to the effects described above, and other effects not described will be clearly understood from the following description by those skilled in the art.

Although embodiments of the present disclosure have been described in more detail with reference to the accompanying drawings, the present disclosure is not necessarily limited to these embodiments, and various modifications may be made without departing from the technical spirit of the present disclosure. Accordingly, the embodiments disclosed in the present disclosure are not intended to limit the technical idea of the present disclosure, but are for illustrative purposes, and the scope of the technical idea of the present disclosure is not limited by these embodiments. Accordingly, it should be understood that the above-described embodiments are exemplary in all respects and not restrictive. The spirit and scope of the present disclosure should be interpreted by the appended claims and encompass all equivalents falling within the scope of the appended claims.

What is claimed is:

1. A display panel comprising:
a plurality of pixels divided into a plurality of pixel groups,
wherein each of the plurality of pixels includes light-emitting elements connected to a first electrode that is configured to supply an anode voltage and a second electrode that is configured to supply a cathode voltage,
wherein each of the light-emitting elements includes an anode connected to the first electrode and a cathode connected to the second electrode,
wherein anodes of the light-emitting elements included in each pixel group are connected to each other,
wherein a light-emitting element from the light-emitting elements emits light by receiving the cathode voltage controlled such that a difference between the anode voltage and the cathode voltage is greater than or equal to a threshold voltage of the light-emitting element, and
wherein a test voltage is applied to the cathode of the light-emitting element to detect whether an electrical short circuit has occurred between the first electrode and the second electrode.

2. The display panel of claim 1, wherein the anode voltage is controlled such that the light-emitting element emits light at a black-gray level.

3. The display panel of claim 1, wherein the cathode voltage is controlled with a first voltage that turns on the light-emitting element to emit light or a second voltage that turns off the light-emitting element to not emit light.

4. The display panel of claim 3, wherein the first voltage is applied to the cathode of the light-emitting element one pixel at a time among pixels in each of the plurality of pixel groups.

5. The display panel of claim 3, wherein the test voltage is applied to the cathode of the light-emitting element instead of the second voltage.

6. The display panel of claim 3, wherein the test voltage is set such that a difference between the test voltage and the first voltage is greater than or equal to the threshold voltage of the light-emitting element.

7. The display panel of claim 2, wherein the electrical short circuit has occurred between the first electrode and the second electrode is detected according to whether the light-emitting elements of the pixels in the pixel group to which the test voltage is applied emit light at a gray level higher than a black-gray level, and
the test voltage is set such that the light-emitting element emits light at the gray level that is higher than the black-gray level.

8. The display panel of claim 1, wherein the light-emitting element includes a main light-emitting element and a sub-light-emitting element, and
the sub-light-emitting element is driven instead of the main light-emitting element when the main light-emitting element is defective.

9. The display panel of claim 8, wherein, when the electrical short circuit has occurred between the first electrode and the second electrode, sub-light-emitting elements are driven instead of main light-emitting elements of all pixels in the pixel group in which the electrical short circuit has occurred.

10. The display panel of claim 1, wherein the light-emitting element is a micro-sized inorganic light-emitting element.

11. A display device comprising:
a display panel that includes a plurality of pixels divided into a plurality of pixel groups,
wherein each of the plurality of pixels includes light-emitting elements connected to a first electrode that is configured to supply an anode voltage and a second electrode that is configured to supply a cathode voltage,
wherein each of the light-emitting elements includes an anode connected to the first electrode and a cathode electrically connected to the second electrode,
wherein anodes of light-emitting elements included in each pixel group are connected to each other,
wherein a light-emitting element from the light-emitting elements emits light by receiving the cathode voltage controlled such that a difference between the anode voltage and the cathode voltage is greater than a threshold voltage of the light-emitting element, and
wherein a test voltage is applied to the cathode of the light-emitting element to detect whether an electrical short circuit has occurred between the first electrode and the second electrode.

12. The display device of claim 11, wherein the anode voltage is controlled such that the light-emitting element emits light at a black-gray level.

13. The display device of claim 11, wherein the cathode voltage is controlled with a first voltage that turns on the light-emitting element to emit light or a second voltage that turns off the light-emitting element to not emit light.

14. The display device of claim 13, wherein the first voltage is applied to the cathode of the light-emitting element one pixel at a time among pixels in each of the plurality of pixel groups.

15. The display device of claim 13, wherein the test voltage is applied to the cathode of the light-emitting element instead of the second voltage.

16. The display device of claim 13, wherein the test voltage is set such that a difference between the test voltage and the first voltage is greater than or equal to the threshold voltage of the light-emitting element.

17. The display device of claim 12, wherein the electrical short circuit has occurred between the first electrode and the second electrode is detected according to whether the light-emitting elements of the pixels in the pixel group to which the test voltage is applied emit light at a gray level higher than a black-gray level, and
the test voltage is set such that the light-emitting element emits light at the gray level higher than the black-gray level.

18. The display device of claim 11, wherein the light-emitting element includes a main light-emitting element and a sub-light-emitting element, and
the sub-light-emitting element is driven instead of the main light-emitting element when the main light-emitting element is defective.

19. The display device of claim 18, wherein, when the electrical short circuit has occurred between the first electrode and the second electrode, sub-light-emitting elements are driven instead of main light-emitting elements of all pixels in the pixel group in which the electrical short circuit has occurred.

20. The display device of claim 11, wherein the light-emitting element is a micro-sized inorganic light-emitting element.
